(19) United States
(12) Patent Application Publication
(10) Pub. No.: US 2001/0040479 A1
(43) Pub. Date: Nov. 15, 2001

(54) Electronic switch

(76) Inventor: Shuyun Zhang, Brookline, MA (US)

Correspondence Address: BROMBERG & SUNSTEIN LLP, 125 SUMMER STREET, BOSTON, MA, 02110-1618, US

(21) Appl. No.: 09/798,326

(22) Filed: Mar. 2, 2001

Related U.S. Application Data
(60) Provisional application No. 60/186,881, filed on Mar. 3, 2000.

(51) Int. Cl. H03K 17/687

(52) U.S. Cl. 327/427

(57) ABSTRACT

An electronic switch structure is disclosed. Capacitors are employed to bias gate-source and gate-drain connections in multi-gate or multi-FET structures achieving linear switch operation over a wide range of signal input power values.

This application claims priority from U.S. Provisional Application Ser. No. 60/186,881 filed Mar. 3, 2000, which is incorporated herein by reference in its entirety.

### TECHNICAL FIELD

The present invention relates to electronic devices and more particularly to semiconductor switches.

### BACKGROUND OF THE INVENTION

In personal wireless communications, competition has driven manufacturers to reduce the size and weight of cellular handsets. One technique for size and weight reduction is the use of a 3V battery in handsets. Traditional transmit/receive (“T/R”) switches, which are employed in such handsets, are not suitable for operation with 3V batteries because of the production of nonlinear signal distortions, as explained below.

A “prior art” single gate single-pole-double-throw (“SPDT”) switch is shown in FIG. 1. Assuming that the switch is controlled with Vctrl=3V and \overline{Vctrl}=0V, FET1 is ON and FET2 is OFF because of the differential bias across the gate-source junction of the FETs (Vb). It is also assumed that the input RF voltage signal is Vᵢₙ·sin (ωt). The voltage at each test point, as shown in FIG. 1, is expressed as follows,

V_{TP1}=Vin· Sin (ωt)+Vctrl−vb; (1)

V_{TP2}=S21·Vin· Sin (ωt)+Vctrl−Vb; (2)

V_{TP3}=S31·S21·Vin· Sin (ωt)+Vctrl−Vb; (3)

$$\begin{matrix}{V}_{TP4} = \frac{1}{2} ( 1 + S21 ) \cdot Vin \cdot Sin ( ω t ) + Vctrl ; & ( 4 ) \\ {V}_{TP5} = \frac{1}{2} ( 1 + S31 ) \cdot S21 \cdot Vin \cdot Sin ( ω t ) + \overline{Vctrl} ; & ( 5 )\end{matrix}$$

where S21 and S31 are the small signal S-parameter and ω is the operating frequency.

The gate-source voltage, Vgs, and the gate-drain voltage, Vgd, of the FETs can be written as:

$$\begin{matrix}{V}_{gs1} = Vb + \frac{1}{2} ( 1 - S21 ) \cdot Vin \cdot Sin ( ω t ) , & ( 6 ) \\ {V}_{gd1} = Vb - \frac{1}{2} ( 1 - S21 ) \cdot Vin \cdot Sin ( ω t ) , & ( 7 ) \\ {V}_{gs2} = Vb + \frac{1}{2} S21 \cdot ( 1 - S31 ) \cdot Vin \cdot Sin ( ω t ) + \overline{Vctrl} - Vctrl , & ( 8 ) \\ {V}_{gd2} = Vb - \frac{1}{2} S21 \cdot ( 1 - S31 ) \cdot Vin \cdot Sin ( ω t ) + \overline{Vctrl} - Vctrl , & ( 9 )\end{matrix}$$

where subscripts “1” and “2” indicate the Vgs and Vgd of FET1 and FET2 respectively. Vgs and Vgd determine the transmission properties of the FETs. Vgs1 and Vgd1 must be high enough to keep FET1 ON, that is Vgd1 and Vgs1 must be greater than Vp, where Vp is the pinchoff voltage of the FET, while Vgs2 and Vgd2 must be low enough to keep FET2 OFF (much less than Vp) in such a manner the switch does not compress the input signal. If Vgd1 and Vgs1 are not greater than Vp, and Vgd2 and Vgs2 not much less than Vp, then FET1 and FET2 will be in a state between fully ON and fully OFF. The output voltage or current is, therefore, distorted in this state. Assuming Vb=0.4V, input power Pin =34.5 dBm, insertion Loss=−0.5 dB and isolation=−20 dB. Then Vin=16.78V, |S21|=0.99 and |S31|=0.1. From Equations (6) and (7), then

V_{gs1}=0.4+0.084· Sin (ωt), (10)

V_{gd1}=0.4−0.084· Sin (ωt). (11)

From equations (10) and (11), FET1 is shown to be ON at all times since Vgs1 and Vgd1 are much greater than Vp and FET1 is always forward biased. Therefore, any output compression is caused by FET2. When the input power is high, Vin is high; Vgd2 or Vgs2 is greater than Vp; and, FET2 starts to turn ON causing signal distortion. Therefore, the amount of power input into such a switch is limited by FET2. To estimate how much power FET2 can handle without distorting the signal, Vgs is replaced with Vp in equations (8) and (9) to get maximum Vin for linear operation,

$${V}_{in max} = \frac{2 \cdot ( Vb - Vp + \overline{Vctrl} - Vctrl )}{\vert S21 \vert \cdot ( 1 - \vert S31 \vert )} . \qquad ( 12 )$$

Vctrl is then related to the maximum input power, Pin max, by equation (13).

$${P}_{in max} = {\frac{2}{{R}_{0}} [ \frac{( Vb - Vp + \overline{Vctrl} - Vctrl )}{\vert S21 \vert \cdot ( 1 - \vert S31 \vert )} ]}^{2} , \qquad ( 13 )$$

where Ro is system impedance.

FIG. 2 is a plot of the relationship among Vgs2, Vgd2 and input power level from equation (13). From FIG. 2, the maximum input power for the switch to operate linearly is about 22 dBm. If the input power is greater than 22 dBm, then Vgs2 or Vgd2 becomes greater than Vp, and FET2 starts to turn ON. Thus, the switch's output signal compresses at an input power above 22 dBm and this compression causes an increase in harmonic distortion.

### Multiple Gate and Multiple FET Structures

As described above, it is known in the art that the power handling capability of a single gate SPDT is related to Vctrl and Vp. Normally, Vctrl is a fixed value, which is determined by the operational voltage of the circuit, and Vp is fixed by the process of manufacture for the FET. To increase the input signal power capacity of SPDT switches, designers have used multi-gate FETs as shown in FIG. 3A in place of the single-gate FETs of FIG. 1. The multi-gate FET switch as shown in FIG. 3B handles more input signal power than the single-gate FET switch. Using equations (8) and (9) it is easily shown that “1/(2n)” can replace the factor “½” for multi-gate FETs, where n is the number of gate(s), i.e., n=1, for a single gate , n=2 for a dual-gate and n=3 for a triple gate, etc. This substitution is possible because the parasitic capacitance of the OFF FET serves as an AC voltage divider.

We can rewrite equation (13) for the multi-gate FET case as follows

$${P}_{in max} = {\frac{2 {n}^{2}}{{R}_{0}} [ \frac{( Vb - Vp + \overline{Vctrl} - Vctrl )}{\vert S21 \vert \cdot ( 1 - \vert S31 \vert )} ]}^{2} . \qquad ( 14 )$$

Estimated maximum linear output power and insertion loss of a switch using different values of n are shown in FIG. 3C. FIG. 3C shows that the insertion loss increases linearly with the number of gates, n, while the maximum input power approaches saturation when n is four or greater. Alternatively, single gate FETs, may be used in place of a multi-gate FET by connecting a plurality of single gate FETs in series, which is a so-called “multi-FET” device FIG. 3D.

Using a small signal model, both FET structures can be modeled as a resistor in parallel with a capacitor, as shown in FIG. 4. The multi-FET structure has better insertion loss and isolation when compared to the multi-gate FET device. This results from the capacitance, Coff, of the multi-gate FET structure, being greater than the total Coff of the multi-FET structure. FIG. 5 shows the difference in Coff between the multi-gate FET and the multi-FET structures. However, in high frequency applications, such as in GigaHertz telephones, microwave circuits, cellular phones and high speed wireless data communications devices, these switches fail to provide adequate isolation, as shown in FIG. 6. These switches further fail when the differential voltage between \overline{Vctrl} and Vctrl is reduced as in switches with low control voltages, when presented with high signal input power. Further, these circuit structures do not allow for low insertion loss and high isolation from interference when operated with a low control voltage at high input signal power.

It should be understood by one of ordinary skill in the art that the conventions of drain and source for a FET structure are used and that the terms drain and source may be used interchangeably assuming a symmetric FET. Such symmetry will be presumed unless the context indicates otherwise.

### SUMMARY OF THE INVENTION

In accordance with a preferred embodiment of the present invention, a device is provided for electronically switching radio frequency signals. The device includes a multigate field effect transistor; a capacitor that connects the transistor's drain to a first gate of the transistor and a capacitor that connects the transistor's source to a second gate of the transistor.

According to a further embodiment of the invention, a device is provided for electronically switching radio frequency signals. The device comprises a group of field effect transistors, connected in a series with the drain of each transistor connected to the source of the succeeding transistor in the series, such that a signal flows into a source of a first transistor and exits from the drain of a last transistor in the series where a channel is formed. The device further comprises a first capacitor connected between the gate and source of the first transistor ensuring that the voltage between gate and source of the first transistor is kept below a pinch off voltage when a control voltage to close the channel is applied to the first transistor's gate. The device further comprises a second capacitor connected between the gate and the drain of the last transistor ensuring that the voltage between gate and drain of the last transistor is kept below a pinch off voltage when a control voltage to close the channel is applied to the last transistor's gate.

In accordance with a further embodiment of the invention, an electronic switch for radio frequency signals is provided. The switch comprises means for switching an electrical signal from an input terminal to an output terminal, a means for reducing a first impedance between the input terminal and a first gate input of the switching means, and a means for reducing a second impedance between the output terminal and a second gate input of the switching means.

In accordance with another embodiment of the invention, a method is provided for electronically switching radio frequency signals. The method has the steps of: providing a first multigate transistor having at least a first gate and a last gate and a source and a drain; coupling a capacitor between the source and the first gate of the first transistor; coupling a capacitor between the drain and the last gate of the first transistor; providing a second multigate transistor having at least a first gate and a last gate and a source and a drain; coupling a capacitor between the source and the first gate of the second transistor; coupling a capacitor between the drain and the last gate of the second transistor.

In accordance with a further embodiment of the invention, a method is provided for electronically switching radio frequency signals. The method comprises: providing a first group of field effect transistors having at least a first transistor and a last transistor wherein each field effect transmitter has a source, a drain and a gate; coupling a capacitor between the source and the gate of the first field effect transistor in the first group; coupling a capacitor between the drain and the gate of the last field effect transistor in the first group; providing a second group of field effect transistors having at least a first transistor and a last transistor wherein each field effect transmitter has a source, a drain and a gate; coupling a capacitor between the source and the gate of the first field effect transistor in the second group; coupling a capacitor between the drain and the gate of the last field effect transistor in the second group; and coupling the first group and the second group creating a transmission port.

### BRIEF DESCRIPTION OF THE DRAWINGS

The foregoing features of the invention will be more readily understood by reference to the following detailed description taken with the accompanying drawings:

FIG. 1 is a schematic diagram of a prior art SPDT switch using single gate FETs;

FIG. 2 is a graph showing Vgd2 (max) or Vgs2 (max) versus input signal power level for the prior art switch of FIG. 1;

FIG. 3A is schematic diagram of a prior art multi-gate FET structure;

FIG. 3B is a schematic diagram of a multi-gate FET SPDT switch;

FIG. 3C is graph showing the maximum linear input power and the insertion loss versus the number of gates for a multi-gate FET switch;

FIG. 3D is a schematic diagram of a multi-FET structure;

FIG. 4 is a schematic diagram showing simplified small signal OFF FET model for the multi-gate and multi-FET switch structure of FIG. 3A and FIG. 3D;

FIG. 5 is a graph showing Coff of the multi-gate FET and the multi-FET switches as a function of the number of gates;

FIG. 6 is a graph showing the isolation of the triple-gate FET and the triple-FET structures as a function of frequency;

FIG. 7 is a graph showing Vgdi and Vgsi as a function of time for the triple-FET in series structure;

FIG. 8 is a schematic diagram of one embodiment of the invention showing a triple FET in series structure with capacitors to suppress Vgd1 and Vgs3;

FIG. 9 is a graph showing Vgsi and Vgdi as a function of time of one embodiment of the invention for a triple FET structure;

FIG. 10 is a schematic diagram showing a multi-gate FET structure with external capacitors;

FIG. 11 is a schematic diagram showing a multi-FET structure with external capacitors;

FIG. 12 is a schematic diagram showing a SPDT switch implemented with a multi-gate FET structure; and

FIG. 13 is a schematic diagram showing a SPDT switch implemented with a multi-FET structure.

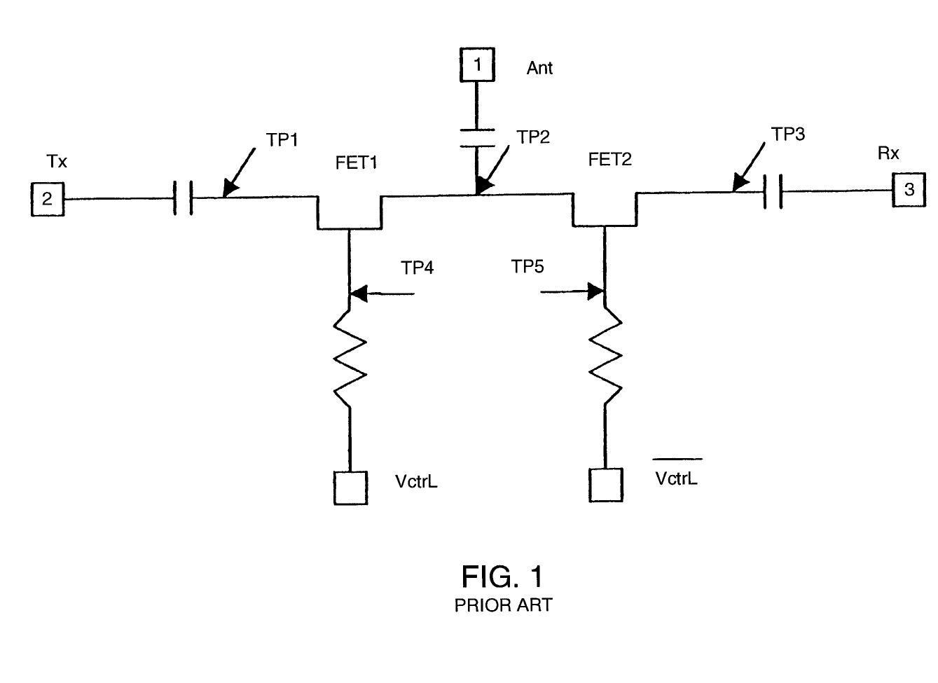

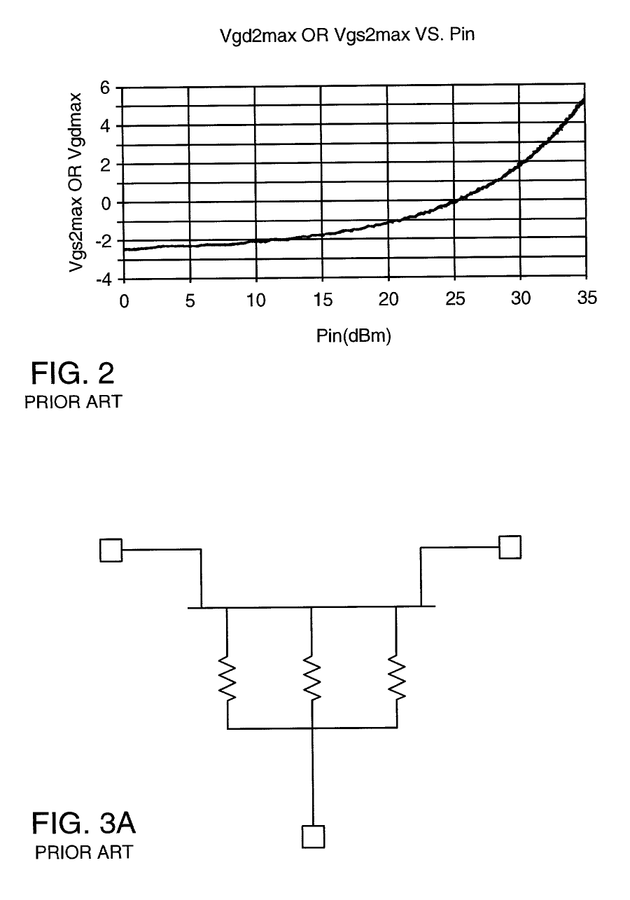

### DETAILED DESCRIPTION OF SPECIFIC EMBODIMENTS

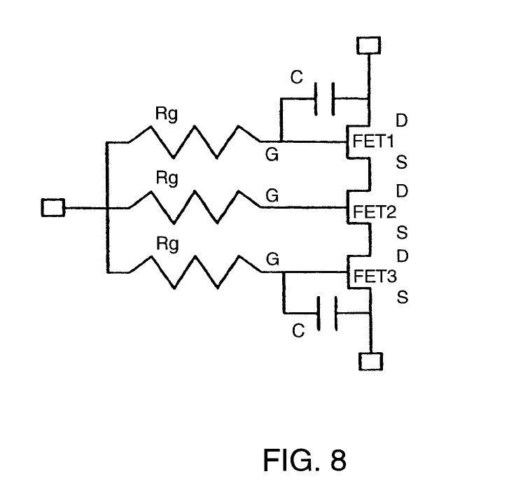

FIG. 8 shows an embodiment of the invention, which is an improved T/R switch that may operate at high frequencies, with high input power (approximately above 20 dBm), and low control voltage and that exhibits low insertion loss and high isolation. These desirable characteristics, which are not found in prior art devices, result from the addition of capacitors C, as shown.

If we extend equations (8) and (9) to three FETs in series, we get the following equations

$$\begin{matrix}{V}_{gdt} = Vb - \frac{1}{6} S21 \cdot ( 1 - S31 ) \cdot Vin \cdot Sin ( ω t ) + \overline{Vctrl} - Vctrl , & ( 15 ) \\ {V}_{gst} = Vb + \frac{1}{6} S21 \cdot ( 1 - S31 ) \cdot Vin \cdot Sin ( ω t ) + \overline{Vctrl} - Vctrl , & ( 16 )\end{matrix}$$

where i=1, 2 and 3 indicate each FET in the series.

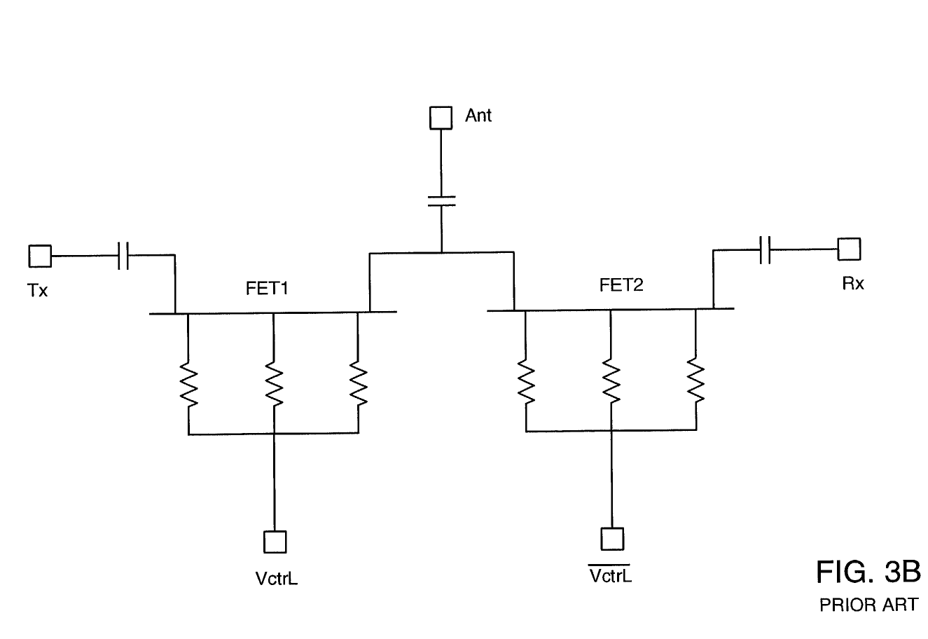

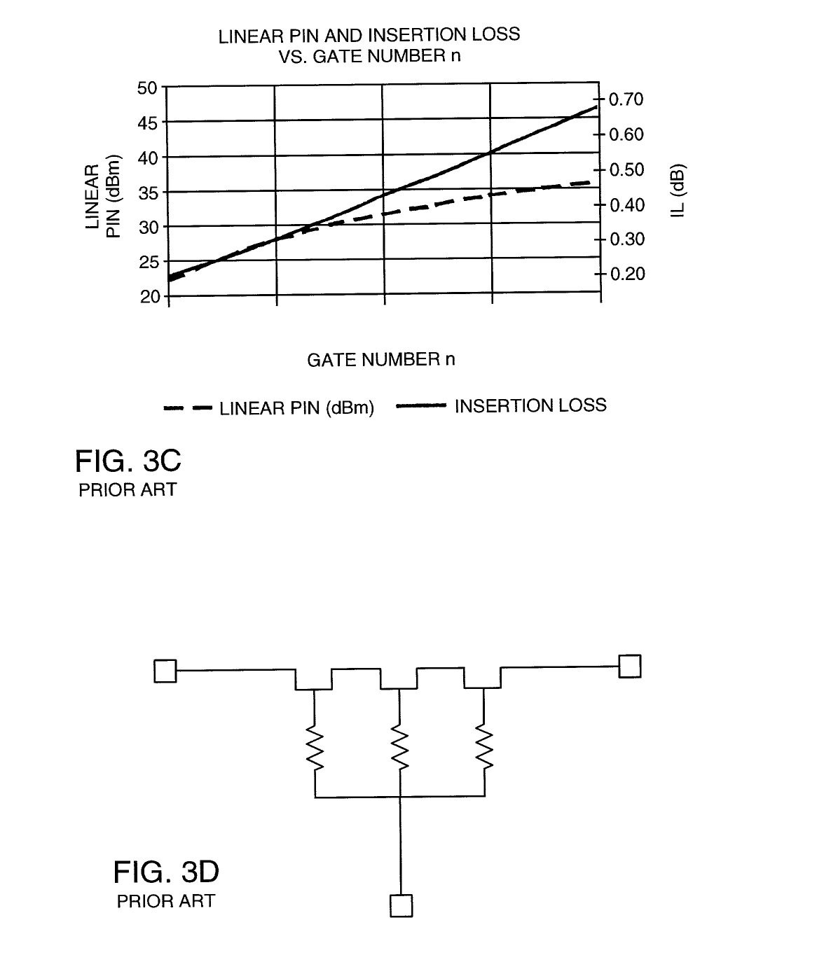

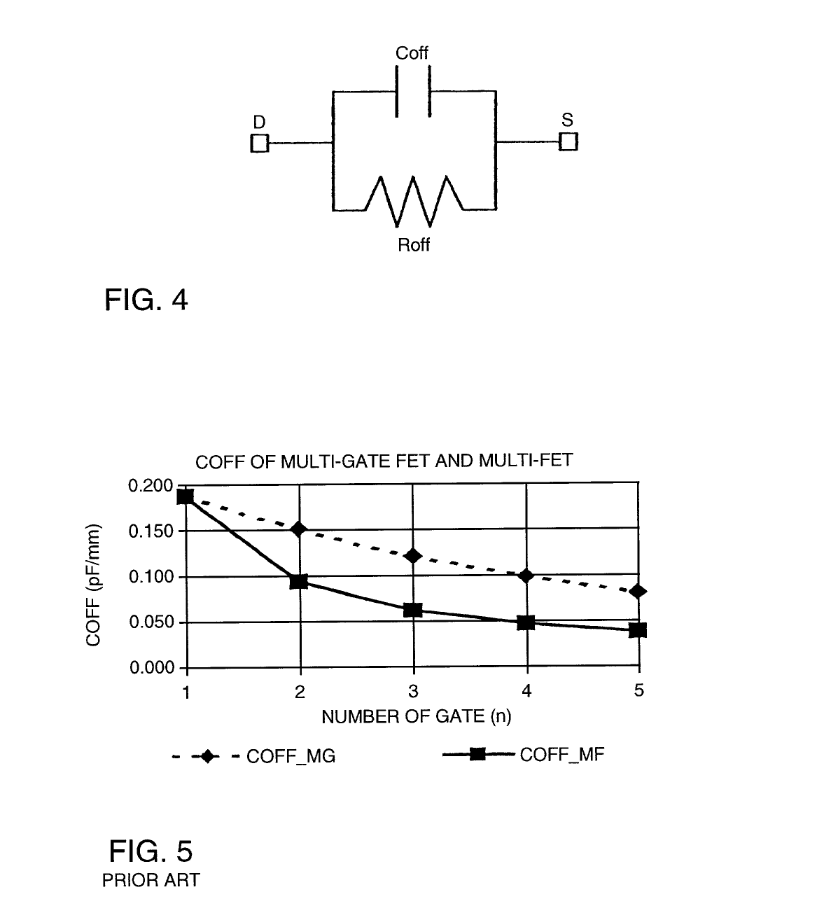

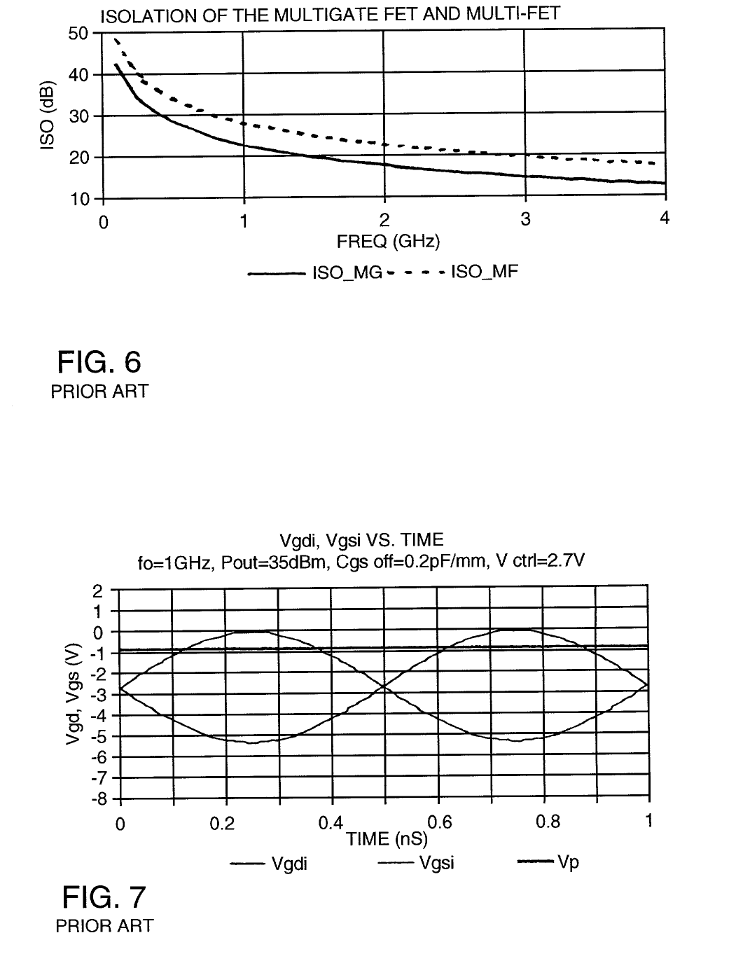

It should be recognized that the AC components of Vgdi and Vgsi (i=1,2,3) are out of phase, as shown in FIG. 7. Because the AC components of Vgdi and Vgsi (i=1,2,3) are out of phase, in the first half period, without capacitors C, Vgdi>Vp for a short time, and, in the second half period, Vgsi>Vp for a short time. This phenomena causes the major harmonic distortion in the prior art T/R switch of FIG. 3B. Introduction of the capacitors, C, in this invention serves to suppress Vgdi in the first half period and Vgsi in the second half period. The result is that Vgdi<Vp in the first half period and Vgsi<Vp in the second half period. Thus, the OFF FET is prevented from turning ON. During the first half period, capacitor C, which is attached between the gate and drain of FET1, reduces the magnitude of Vgd1 and in the second half of the period, the other capacitor C, which is between the gate and the source of FET3, reduces the magnitude of Vgs3. The result is that in the first half of the period, FET1 is OFF and in the second half of the period FET3 is OFF. Since the three FETs are connected in series, the OFF FET path is OFF over the whole period. If the value of capacitor C is much greater than Cgsoff, then Vgdi and Vgsi can be expressed, in a fashion similar to equations (15) and (16), as shown in equations (17) and (18).

$$\begin{matrix}\begin{matrix}{V}_{gd1} = Vb - \frac{{C}_{gsoff}}{6 {C}_{gsoff} + 4 C} S21 \cdot ( 1 - S31 ) \cdot Vin \cdot Sin ( ω t ) + \\ \overline{Vctrl} - Vctrl ,\end{matrix} & ( 17 \\ \begin{matrix}{V}_{gs1} = Vb + \frac{{C}_{gsoff} + C}{6 {C}_{gsoff} + 4 C} S21 \cdot ( 1 - S31 ) \cdot Vin \cdot Sin ( ω t ) + \\ \overline{Vctrl} - Vctrl ,\end{matrix} & ( 18 ) \\ \begin{matrix}{V}_{gd2} = Vb - \frac{{C}_{gsoff} + C}{6 {C}_{gsoff} + 4 C} S21 \cdot ( 1 - S31 ) \cdot Vin \cdot Sin ( ω t ) + \\ \overline{Vctrl} - Vctrl ,\end{matrix} & ( 19 ) \\ \begin{matrix}{V}_{gs2} = Vb + \frac{{C}_{gsoff} + C}{6 {C}_{gsoff} + 4 C} S21 \cdot ( 1 - S31 ) \cdot Vin \cdot Sin ( ω t ) + \\ \overline{Vctrl} - Vctrl ,\end{matrix} & ( 20 ) \\ \begin{matrix}{V}_{gd3} = Vb - \frac{{C}_{gsoff} + C}{6 {C}_{gsoff} + 4 C} S21 \cdot ( 1 - S31 ) \cdot Vin \cdot Sin ( ω t ) + \\ \overline{Vctrl} - Vctrl ,\end{matrix} & ( 21 ) \\ \begin{matrix}{V}_{gs3} = Vb + \frac{{C}_{gsoff}}{6 {C}_{gsoff} + 4 C} S21 \cdot ( 1 - S31 ) \cdot Vin \cdot Sin ( ω t ) + \\ \overline{Vctrl} - Vctrl ,\end{matrix} & ( 22 )\end{matrix}$$

where Cgsoff represents the gate-drain or gate-source parasitic capacitance. If we make C>>Cgsoff then Vgd1max=Vgs3max≈Vb-Vctrl. It should be understood by one of ordinary skill in the art that the capacitor values, C, at FET1 and at FET2, which have been assumed to be identical, may differ. Similarly, Cgsoff is assumed to be the same for all three FETs and also may differ.

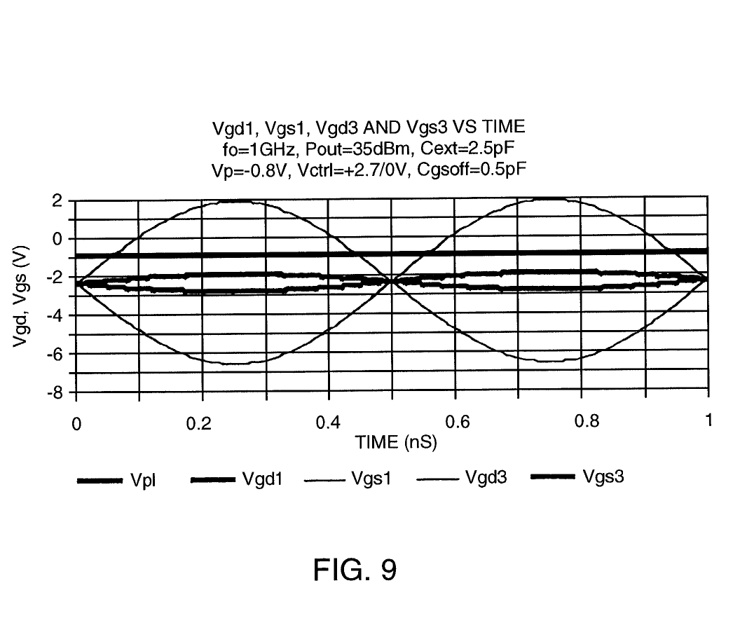

The AC component of Vgd1 and of Vgs3 are opposite in phase, such that in the first half period FET3 is OFF and in the second half period FET1 is OFF, as plotted in FIG. 9. This technique prevents the OFF FET from turning ON over the whole period, creating a low control voltage, high power switch. The frequency range over which this switch functions may be extended to lower frequencies by increasing the value of capacitor C. The advantages described are not limited to SPDT switches but apply equally to NPnT switches, where n and N are greater than or equal to one.

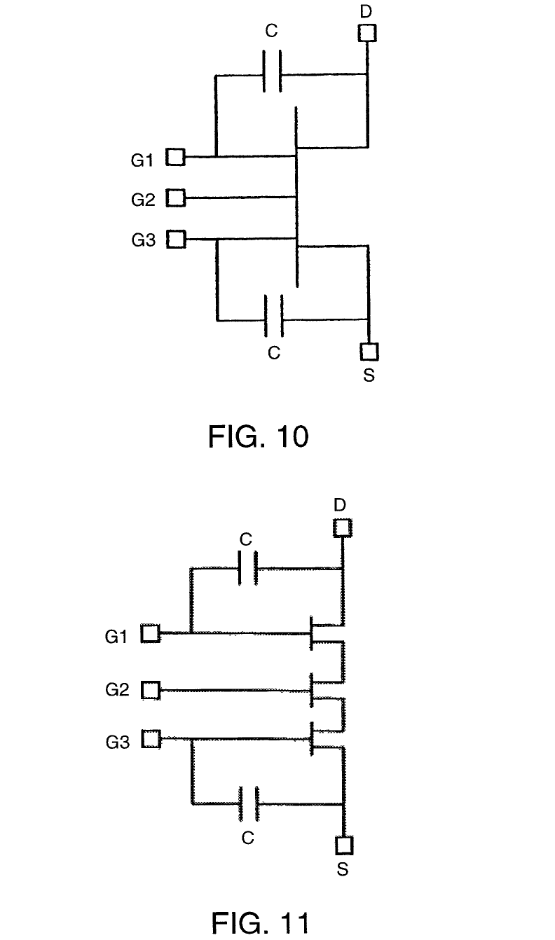

FIG. 10 shows an exemplary multi-gate FET structure for operation with microwave signals. Such a structure would exhibit the advantages described above assuming the switch is operating on a 1 GHz frequency signal, the structure has a gate periphery of 2 millimeters and the capacitors C are 6 picoFarad capacitors. It should be understood that these values are meant merely as an example of an operational switching structure, however other frequency, periphery, and capacitor combinations may be used without altering the nature of the invention. Similar advantageous results may be achieved with the multi-FET structure of FIG. 11.

The switch of the embodiments described above provides a number of advantages. The switch is not sensitive to electrostatic discharge (“ESD”), being complient with the industry standard 250 volt ESD test. The switch provides ultra high isolation at high frequencies, exhibiting 27 dB of isolation at 1 GHz. The switch exhibits ultra high linearity, with greater than 70 dBc for the second and third harmonics. The switch provides ultra high power capability with greater than 37 dBm of P−0.1 dB. Further, the switch is operational at low control voltage differentials of ˜2.5V.

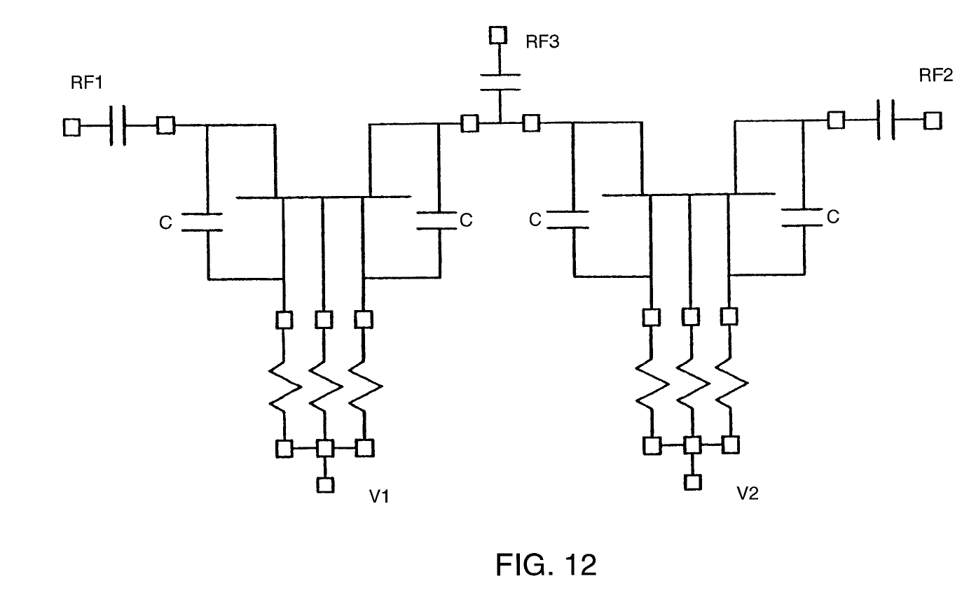

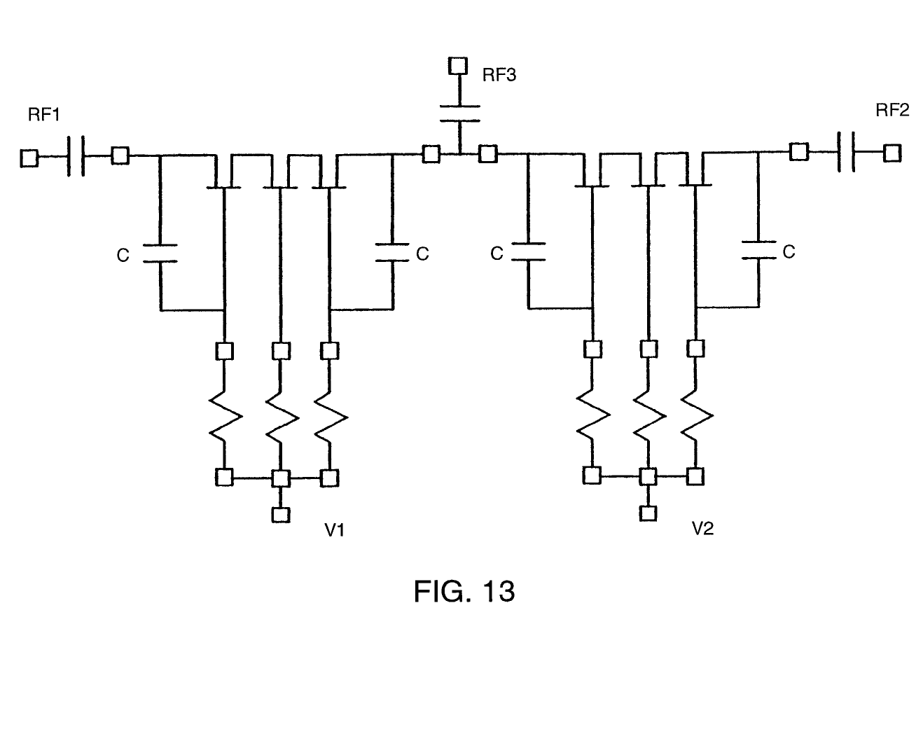

FIGS. 12-13 show various embodiments of the above-disclosed invention as applied to an SPDT T/R switch. FIG. 12 is a schematic diagram showing one embodiment of the invention for a SPDT switch implemented with a multi-gate FET structure. FIG. 13 is a schematic diagram showing one embodiment of the invention for an SPDT switch implemented with a multi-FET structure.

Although various exemplary embodiments of the invention have been disclosed, it should be apparent to those skilled in the art that various changes and modifications can be made which will achieve some of the advantages of the invention without departing from the true scope of the invention. These and other obvious modifications are intended to be covered by the appended claims.

I claim:

1. An electric switch, the electric switch comprising:
a multigate field effect transistor having a plurality of gates, a drain and a source, the transistor having a first gate which is proximate to the drain and a second gate which is proximate to the source;
a first capacitor connecting the drain to the first gate; and
a second capacitor connecting the source to the second gate.

2. An electric switch according to claim 1 wherein the plurality of gates are electrically coupled.

3. An electric switch according to claim 1, wherein a control voltage having a high and a low state may be applied to a gate and wherein the difference between the high and the low state is less than 5 volts.

4. An electric switch according to claim 1, wherein a control voltage having a high and a low state may be applied to a gate and wherein the difference between the high and the low state is less than 3.3 volts.

5. An electric switch according to claim 1, wherein a control voltage having a high and a low state may be applied to a gate and wherein the difference between the high and the low state is less than 3.0 volts.

6. An electric switch according to claim 1 wherein a control voltage having a high and a low state may be applied to a gate and wherein the difference between the high and the low state is less than 2.6 volts.

7. An electric switch according to claim 1, wherein the electric switch is a microwave switch and operates at microwave frequencies.

8. An electric switch according to claim 1, wherein the microwave frequencies are above 1 Ghz.

9. An electric switch according to claim 7, wherein the power of the received microwave circuit is above 37 dBm of P−0.1 dB.

10. An electric switch according to claim 1, wherein a control voltage having a high and a low state may be applied to a gate and wherein the first capacitor is of such a capacitance that the gate to source voltage at the first gate is kept below a pinch-off voltage for the transistor when a control voltage having a low state is applied to the first gate.

11. An electric switch according to claim 1, wherein the first capacitor has a capacitance which is greater than C_{gsoff}.

12. An electric switch according to claim 1, wherein the second capacitor has a capacitance which is greater than C_{gsoff}.

13. An electric switch according to claim 1, further comprising:
a second field effect transistor having a plurality of gates, a drain and a source, the second field effect transistor having a first gate which is proximate to the drain and a second gate which is proximate to the source;
a third capacitor connecting the first gate and drain of the second field effect transistor;
a fourth capacitor connecting the second gate and source of the second field effect transistor;
wherein the third capacitor and the second capacitor are electrically coupled.

14. An electric switch according to claim 13 wherein the switch is a transmit and receive switch and wherein an input for sending and receiving is connected to the compling of the second and third capacitors.

15. An electric switch, the switch comprising:
a group of field effect transistors, each field effect transistor in the group having a gate, a drain and a source, the transistors connected in series source to drain first to last, wherein a signal flows into the source of the first transistor in the group of transistors and exits the drain of a last transistor in the group when a channel is formed, a control voltage having a high and a low state may be applied to a gate to open or close the channel;
a first capacitor connected between the gate and the source of the first transistor for keeping a voltage between the gate and the source of the first transistor below a pinch off voltage for the first transistor when a control voltage to close the channel is applied to the gate of the first transistor; and
a second capacitor connected between the gate and the drain of the last transistor for keeping the voltage at the gate of the last transistor below a pinch-off voltage for the last transistor when a control voltage to close the channel applied to the gate of the last transistor.

16. An electric switch according to claim 15, wherein during a period divided into a first and a second half when an alternating current signal is applied, the first capacitor maintains the first transistor in an off state during the first half of the period and the second capacitor maintains the last transistor in an off state during the second half of the period.

17. An electric switch according to claim 15, further comprising
a second group of field effect transistors, each field effect transistor in the group having a gate, a drain and a source, the transistors connected in series from first to last, wherein a signal flows into the source of the first transistor in the group of transistors and exits the drain of a last transistor in the group when a channel is formed wherein a control voltage having a high and a low state may be applied to a gate to open or close the channel;
a third capacitor connected between the gate and the source of the first transistor of the second group for keeping a voltage between the gate and the source of the first transistor of the second group below a pinch off voltage for the first transistor when a control voltage to close the channel is applied to the gate; and
a fourth capacitor connected between the gate and the drain of the last transistor of the second group for keeping the voltage at the gate of the last transistor of the second group below a pinch-off voltage for the last transistor of the second group when a control voltage to close the channel is applied to the gate of the last transistor.

18. The switch according to claim 17, further comprising:
a signal port connected to the second and third capacitors for receiving and sending a microwave signal.

19. An electric switch according to claim 15, wherein the difference between the high and the low state is less than 5 volts.

20. An electric switch according to claim 15, wherein the difference between the high and the low state is less than 3.3 volts.

21. An electric switch according to claim 15, wherein the difference between the high and the low state is less than 3.0 volts.

22. An electric switch according to claim 15, wherein the difference between the high and the low state is less than 2.6 volts.

23. An electric switch according to claim 15, wherein the electric switch is a microwave switch and operates at microwave frequencies.

24. An electric switch according to claim 15, wherein the microwave frequencies are above 1 Ghz.

25. An electric switch, the electric switch comprising:
a means for switching an electrical signal from an input terminal to an output terminal;
a means for reducing a first impedance between the input terminal and a first gate input of the switching means; and
a means for reducing a second impedance between the output terminal and a second gate input of the switching means.

26. A method for creating an electric switch comprising:
providing a first multigate transistor having at least a first gate and a last gate and a source and a drain;
electrically coupling a capacitor between the source and the first gate of the first multigate transistor;
electrically coupling a capacitor between the drain and the last gate of the first multigate transistor;
providing a second multigate transistor having at least a first gate and a last gate and a source and a drain.
electrically coupling a capacitor between the source and the first gate of the second multigate transistor;
electrically coupling a capacitor between the drain and the last gate of the second multigate transistor.

27. A method for creating an electric switch comprising:
providing a first group of field effect transistors having at least a first transistor and a last transistor wherein each field effect transmitter has a source, a drain and a gate;
electrically coupling a capacitor between the source and the gate of the first field effect transistor in the first group;
electrically coupling a capacitor between the drain and the gate of the last field effect transistor in the first group;
providing a second group of field effect transistors having at least a first transistor and a last transistor wherein each field effect transmitter has a source, a drain and a gate;
electrically coupling a capacitor between the source and the gate of the first field
effect transistor in the second group;
electrically coupling a capacitor between the drain and the gate of the last field effect transistor in the second group; and
electrically coupling the first group and the second group creating a transmission port.
